(19) United States
(12) Patent Application Publication
(10) Pub. No.: US 2011/0226731 A1
(43) Pub. Date: Sep. 22, 2011

(54) CRYSTAL SUBSTRATE ETCHING METHOD, PIEZOELECTRIC VIBRATING REED, A PIEZOELECTRIC VIBRATOR, OSCILLATOR, ELECTRONIC DEVICE, AND RADIO-CONTROLLED TIMEPIECE

(76) Inventors: Yoichi Funabiki, Chiba-shi (JP); Kiyoshi Aratake, Chiba-shi (JP)

(21) Appl. No.: 13/050,301

(22) Filed: Mar. 17, 2011

(30) Foreign Application Priority Data
Mar. 19, 2010 (JP) 2010-065131

(51) Int. Cl. H01L 41/22

(52) U.S. Cl. 216/20; 216/13

(57) ABSTRACT

Provided are a crystal substrate etching method capable of processing with high accuracy, a piezoelectric vibrating reed of which the outer shape is formed by the method, a piezoelectric vibrator having the piezoelectric vibrating reed, and an oscillator, an electronic device, and a radio-controlled timepiece having the piezo-electric vibrator. A crystal substrate and an auxiliary substrate are successively dry-etched from a second surface side of the crystal substrate in a state where the auxiliary substrate having approximately the same etching rate as the crystal substrate is bonded to a first surface of the crystal substrate.

### RELATED APPLICATIONS

This application claims priority under 35 U.S.C. §119 to Japanese Patent Application No. 2010-065131 filed on Mar. 19, 2010, the entire content of which is hereby incorporated by reference.

### BACKGROUND OF THE INVENTION

1. Field of the Invention

The present invention relates to a crystal substrate etching method, a piezoelectric vibrating reed, a piezoelectric vibrator, and an oscillator, an electronic device, and a radio-controlled timepiece each having the piezoelectric vibrator.

2. Background Art

In recent years, piezoelectric vibrators using crystal or the like are being used in mobile phones or portable information terminals as a time source, a control signal timing source, a reference signal source, and the like. Although there are various piezoelectric vibrators of this type, a piezoelectric vibrator in which a so-called tuning-fork type vibrating reed is sealed in a package is known as one example thereof. A tuning-fork-type piezoelectric vibrating reed is a thin plate-like crystal reed which includes a pair of vibrating arms arranged in a line in the width direction thereof and a base portion that integrally fixes base end sides in the longitudinal direction of the pair of vibrating arms.

JP-A-2004-349365 discloses a method of forming the outer shape of a piezoelectric element (corresponding to a piezoelectric vibrating reed of the present invention) by dry-etching a piezoelectric substrate (corresponding to a crystal substrate of the present invention). According to a specific method of forming the outer shape of a piezoelectric vibrating reed, a metal film pattern is formed on the surface of a piezoelectric substrate, and a crystal substrate is dry-etched using the metal film pattern as a mask. In this way, the crystal substrate in regions other than the region protected by the metal film pattern is selectively removed, and the outer shape of the piezoelectric vibrating reed can be formed.

However, the dry-etching is performed by generating plasma in a vacuum chamber, generating active species of ions or the like from an etching gas, and causing a chemical reaction between the active species of ions or the like and the crystal substrate. Here, this chemical reaction is an exothermic reaction, and when the dry-etching is being performed, the crystal substrate is heated to a high temperature. Therefore, there is a possibility that thermal strain may occur in the crystal substrate, and the characteristics of the crystal substrate are deteriorated.

In order to solve the problem, a method of performing dry-etching while cooling the crystal substrate is generally known.

FIG. 23 illustrates a dry-etching method according to the related art.

According to a specific dry-etching method, a silicon substrate 720 is attached to one surface of a crystal substrate 700 by an adhesive 710. Then, the crystal substrate 700 is placed on a cooling device 800 for each silicon substrate 720, and dry-etching is performed in a state where the silicon substrate 720 comes into contact with the cooling device 800. Since the silicon substrate 720 has high thermal conductivity, it is possible to effectively radiate the heat of the crystal substrate 700 to the cooling device 800.

Here, the etching rate of the silicon substrate 720 is much higher than the crystal substrate 700. Therefore, when the silicon substrate 720 is etched so as to penetrate through the crystal substrate 700 and the adhesive 710, there is a possibility that etching may reach the cooling device 800 below the silicon substrate 720 immediately, and the cooling device 800 is damaged. Therefore, in order to prevent the damage to the cooling device 800, the etching stops at the point in time when the etching reaches the adhesive 710.

However, in the above-described dry-etching method according to the related art, since the etching stops at the adhesive 710, it is difficult to over-etch the crystal substrate 700. Therefore, it is unable to process the side surfaces of a hole formed by the etching so as to be vertical to the principal surface. Therefore, it is difficult to form the side surfaces of the piezoelectric vibrating reed with high accuracy.

Moreover, since the thickness of the adhesive 710 is about 100 μm thick, when the etching reaches the adhesive 710 while penetrating through the crystal substrate 700, side-etching progresses along an adhesion surface 700a between the crystal substrate 700 and the adhesive 710. Therefore, the adhesion surface 700a of the crystal substrate 700 is also etched unnecessarily, and it is difficult to form the surface of the piezoelectric vibrating reed with high accuracy.

As described above, the dry-etching method of the related art has a problem in that it is difficult to form the outer shape of the piezoelectric vibrating reed with high accuracy and the characteristics of the piezoelectric vibrating reed are deteriorated.

### SUMMARY OF THE INVENTION

Therefore, it is an object of the present invention to provide a crystal substrate etching method capable of processing with high accuracy, a piezoelectric vibrating reed of which the outer shape is formed by the method, a piezoelectric vibrator having the piezoelectric vibrating reed, and an oscillator, an electronic device, and a radio-controlled timepiece having the piezoelectric vibrator.

According to an aspect of the present invention, there is provided a crystal substrate etching method in which a crystal substrate and an auxiliary substrate are successively dry-etched from a second surface side of the crystal substrate in a state where the auxiliary substrate having approximately the same etching rate as the crystal substrate is bonded to a first surface of the crystal substrate.

According to this configuration, since the auxiliary substrate having approximately the same etching rate as the crystal substrate is bonded to the crystal substrate, etching will not penetrate through the auxiliary substrate immediately. Moreover, by successively dry-etching the crystal substrate and the auxiliary substrate, it is possible to perform over-etching so as to penetrate through the crystal substrate. In this way, since the side surfaces of a hole formed by the etching can be processed to be vertical to a principal surface, it is possible to form the outer shape of the piezoelectric vibrating reed with high accuracy.

In the crystal substrate etching method, it is preferable that the auxiliary substrate is formed of a material containing a silicon oxide as its main component.

According to this configuration, since the material of the auxiliary substrate contains the same main component as the material of the crystal substrate, it is possible to make the etching rate of the auxiliary substrate approximately the same as the etching rate of the crystal substrate.

In the crystal substrate etching method, it is preferable that the crystal substrate and the auxiliary substrate are anodically bonded by an anodic bonding film.

Anodic bonding is a technique of superimposing respective bonding substrates onto each other, applying a voltage and heat thereto, and causing a covalent bonding at the bonding interface, thus bonding the substrates to each other. Since the anodic bonding film is made of aluminum, chromium, or the like, and the etching rate of the anodic bonding film is higher than the etching rate of the crystal substrate, side-etching of the anodic bonding film is hard to progress. Therefore, according to this configuration, it is possible to suppress the first surface of the crystal substrate from being etched. On the other hand, since the anodic bonding film is very thin, the dry-etching progresses without stopping at the anodic bonding film. Therefore, it is possible to perform over-etching so as to penetrate through the crystal substrate. In this way, it is possible to form the outer shape of the piezoelectric vibrating reed with higher accuracy.

In the crystal substrate etching method, it is preferable that the crystal substrate and the auxiliary substrate are hydrogen-bonded.

Hydrogen bonding is a technique of attaching a hydroxy group to the respective bonding surfaces of the respective substrates on which an oxide film is formed, and causing a hydrogen bond between the hydroxy groups of the respective bonding surfaces, thus bonding the substrates to each other. According to this configuration, the crystal substrate and the auxiliary substrate can be seamlessly hydrogen-bonded by a hydrogen bond without using an adhesive or a bonding film. Therefore, the first surface of the crystal substrate is not etched.

In the crystal substrate etching method, it is preferable that the crystal substrate and the auxiliary substrate are bonded at a room temperature.

Room-temperature bonding is a technique of activating the surfaces of the respective bonding substrates and causing the respective bonding surfaces to make close contact with each other, thus bonding the respective substrates. According to this configuration, it is possible to bond the crystal substrate and the auxiliary substrate at the room temperature without performing a heating treatment. By doing so, since no thermal strain occurs in the crystal substrate due to the difference in the linear expansion coefficients between the auxiliary substrate and the crystal substrate, it is possible to bond the crystal substrate and the auxiliary substrate without impairing the characteristics of the crystal substrate. Moreover, the crystal substrate and the auxiliary substrate can be separated easily just by applying gallium to a bonding portion so as to permeate through the interface.

According to another aspect of the present invention, there is provided a piezoelectric vibrating reed of which the outer shape is formed by the crystal substrate etching method according to the above aspect of the present invention.

According to this configuration, since the etching method according to the above aspect of the present invention is capable of forming flat side surfaces after etching with high accuracy, it is possible to form the outer shape of the piezoelectric vibrating reed with high accuracy. Therefore, it is possible to provide a piezoelectric vibrating reed having no manufacturing defects and excellent vibration characteristics.

According to a further aspect of the present invention, there is provided a piezoelectric vibrator having the piezoelectric vibrating reed according to the above aspect of the present invention.

According to this configuration, since the piezoelectric vibrator has the piezoelectric vibrating reed having no manufacturing defects and excellent vibration characteristics, it is possible to provide a piezoelectric vibrator having an excellent performance.

According to a still further aspect of the present invention, there is provided an oscillator in which the piezoelectric vibrator according to the above aspect of the present invention is electrically connected to an integrated circuit as an oscillating piece.

According to a still further aspect of the present invention, there is provided an electronic device in which the piezoelectric vibrator according to the above aspect of the present invention is electrically connected to a clock section.

According to a still further aspect of the present invention, there is provided a radio-controlled timepiece in which the piezoelectric vibrator according to the above aspect of the present invention is electrically connected to a filter section.

According to the oscillator, electronic device, and radio-controlled timepiece according to the above aspects of the present invention, since they have the above-described piezoelectric vibrator having excellent performance, it is possible to provide an oscillator, an electronic device, and a radio-controlled timepiece having excellent performance.

According to the crystal substrate etching method according to the above aspect of the present invention, since the auxiliary substrate having approximately the same etching rate as the crystal substrate is bonded to the crystal substrate, etching will not penetrate through the auxiliary substrate immediately. Moreover, by successively dry-etching the crystal substrate and the auxiliary substrate, it is possible to perform over-etching so as to penetrate through the crystal substrate. In this way, since the side surfaces of a hole formed by the etching can be processed to be vertical to a principal surface, it is possible to form the outer shape of the piezoelectric vibrating reed with high accuracy.

### BRIEF DESCRIPTION OF THE DRAWINGS

FIG. 1 is a perspective view showing an external appearance of a piezoelectric vibrator.

FIG. 2 is a top view showing an inner structure of the piezoelectric vibrator shown in FIG. 1, showing a state where a lid substrate is removed.

FIG. 3 is a cross-sectional view of the piezoelectric vibrator taken along the line A-A in FIG. 2.

FIG. 4 is an exploded perspective view of the piezoelectric vibrator shown in FIG. 1.

FIG. 5 is a top view of a piezoelectric vibrating reed.

FIG. 6 is a bottom view of the piezoelectric vibrating reed.

FIG. 7 is a cross-sectional view taken along the line B-B in FIG. 5.

FIG. 8 is a flowchart of the method for manufacturing a piezoelectric vibrator.

FIG. 9 is a flowchart of a piezoelectric vibrating reed manufacturing step.

FIG. 10 illustrates an auxiliary substrate bonding step according to a first embodiment.

FIG. 11 illustrates a metal film forming step.

FIG. 12 illustrates a photoresist film forming step.

FIG. 13 illustrates a resist pattern forming step.

FIG. 14 illustrates a developing step.

FIG. 15 illustrates a metal film etching step.

FIG. 16 illustrates the removal of a resist pattern.

FIG. 17 illustrates a dry-etching step.

FIG. 18 illustrates a crystal substrate after the dry-etching.

FIG. 19 is an exploded perspective view of a wafer assembly.

FIG. 20 is a view showing the configuration of an oscillator according to an embodiment of the present invention.

FIG. 21 is a view showing the configuration of an electronic device according to an embodiment of the present invention.

FIG. 22 is a view showing the configuration of a radio-controlled timepiece according to an embodiment of the present invention.

FIG. 23 illustrates a dry-etching method according to the related art.

### DETAILED DESCRIPTION OF THE INVENTION

### Piezoelectric Vibrator

Hereinafter, a piezoelectric vibrator according to an embodiment of the present invention will be described with reference to the drawings.

It is assumed that a bonding surface of a base substrate of a piezo-electric vibrator bonded to a lid substrate is a first surface U, and an outer surface of the base substrate is a second surface L.

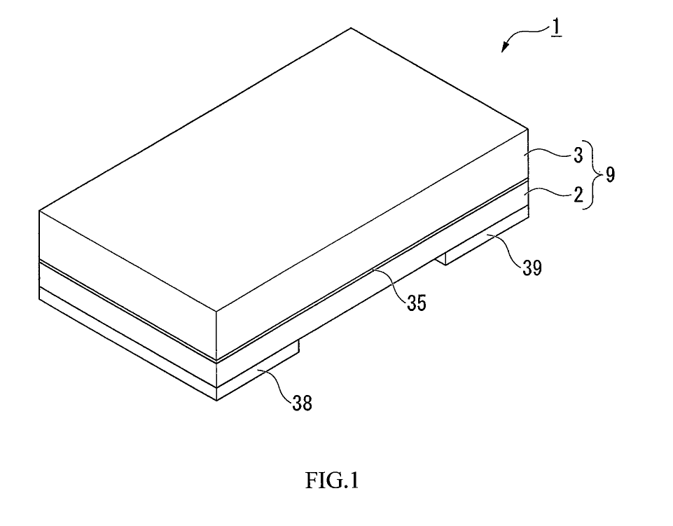

FIG. 1 is a perspective view showing an external appearance of a piezoelectric vibrator according to an embodiment of the present invention.

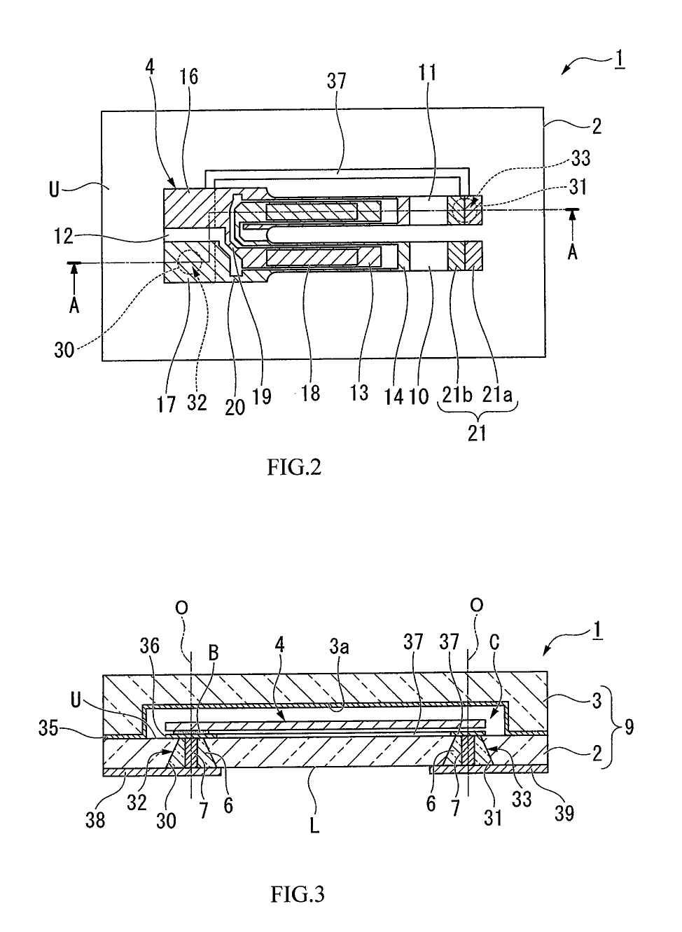

FIG. 2 is a top view showing an inner structure of the piezoelectric vibrator shown in FIG. 1, showing a state where a lid substrate is removed.

FIG. 3 is a cross-sectional view of the piezoelectric vibrator taken along the line A-A in FIG. 2.

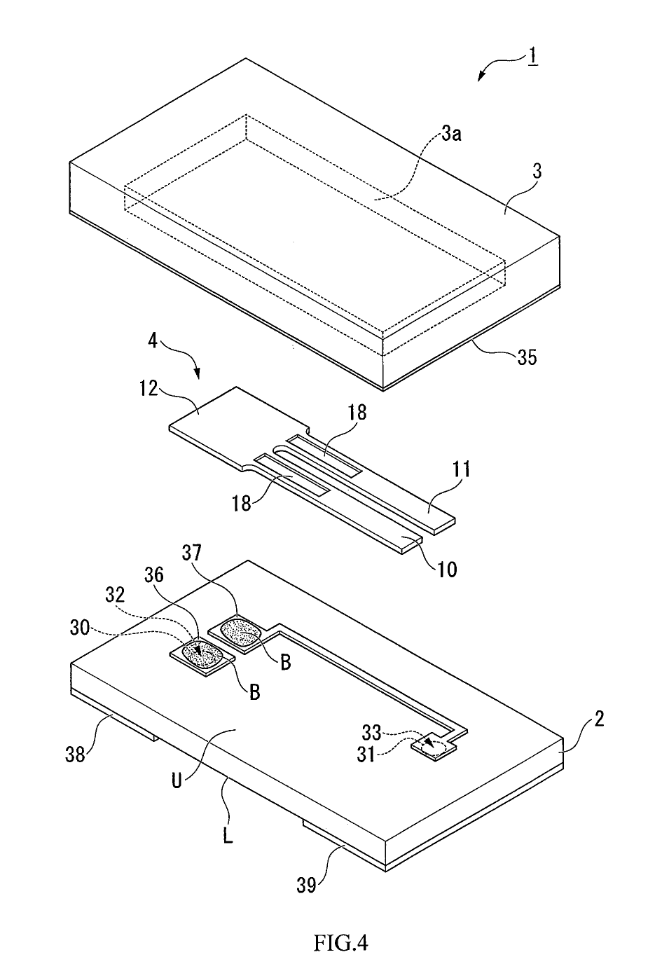

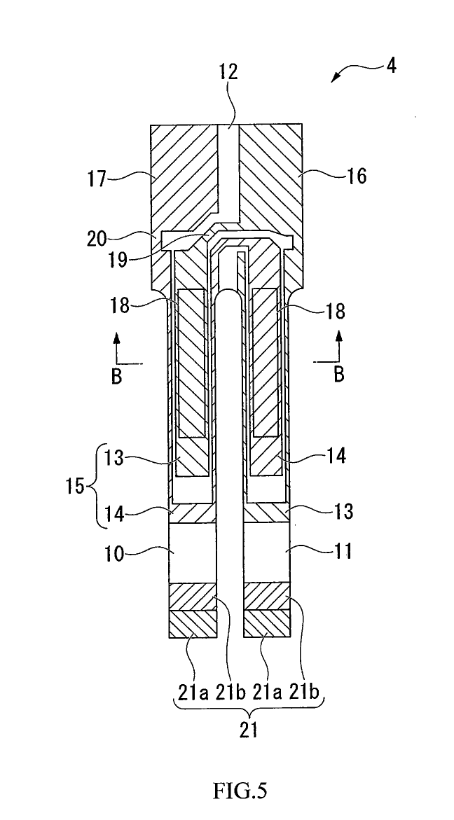

FIG. 4 is an exploded perspective view of the piezoelectric vibrator shown in FIG. 1.

In FIG. 4, for better understanding of the drawings, illustrations of the excitation electrode 15, extraction electrodes 19 and 20, mount electrodes 16 and 17, and weight metal film 21, which will be described later, are omitted.

As shown in FIGS. 1 to 4, a piezoelectric vibrator 1 according to the present embodiment is a surface mounted device-type piezoelectric vibrator 1 which includes a package 9, in which a base substrate 2 and a lid substrate 3 are anodically bonded to each other with a bonding film 35 disposed therebetween, and a piezoelectric vibrating reed 4 which is accommodated in a cavity C of the package 9.

### Piezoelectric Vibrating Reed

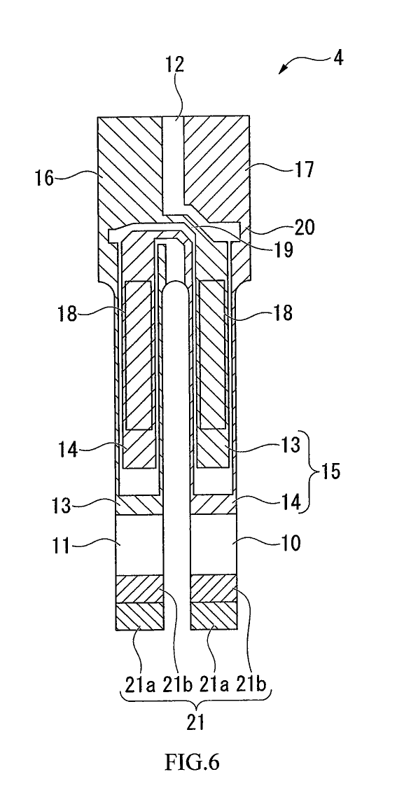

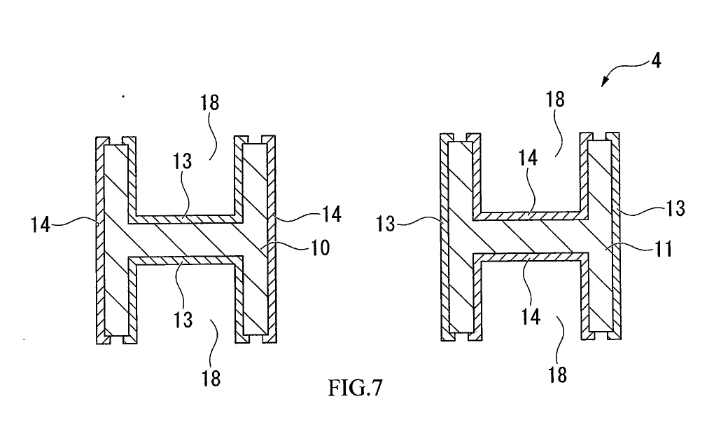

FIG. 5 is a top view of a piezoelectric vibrating reed. FIG. 6 is a bottom view of the piezoelectric vibrating reed. FIG. 7 is a cross-sectional view taken along the line B-B in FIG. 5.

As shown in FIGS. 5 to 7, the piezoelectric vibrating reed 4 is a turning-fork type vibrating reed which is made of crystal and is configured to vibrate when a predetermined voltage is applied thereto. The piezoelectric vibrating reed 4 includes a pair of vibrating arms 10 and 11 disposed in parallel to each other, a base portion 12 to which the base end sides of the pair of vibrating arms 10 and 11 are integrally fixed, and groove portions 18 which are formed on both principal surfaces of the pair of vibrating arms 10 and 11. The groove portions 18 are formed so as to extend from the base end sides of the vibrating arms 10 and 11 along the longitudinal direction of the vibrating arms 10 and 11 up to approximately the middle portions thereof.

The piezoelectric vibrating reed 4 includes: an excitation electrode 15 which is formed on the outer surfaces of the base ends of the pair of vibrating arms 10 and 11 so as to allow the pair of vibrating arms 10 and 11 to vibrate and includes a first excitation electrode 13 and a second excitation electrode 14; mount electrodes 16 and 17 which are formed on the base portion 12 in order to mount the piezoelectric vibrating reed 4 on a package; and extraction electrodes 19 and 20 which electrically connect the first and second excitation electrodes 13 and 14 to the mount electrodes 16 and 17.

In the present embodiment, the excitation electrode 15 and the extraction electrodes 19 and 20 are formed by a single-layered film of chromium (Cr) which is the same material as the base layer of mount electrodes 16 and 17 described later. Therefore, it is possible to form the excitation electrode 15 and the extraction electrodes 19 and 20 at the same time as the forming of the base layer of the mount electrodes 16 and 17. However, the present invention is not limited to this, the excitation electrode 15 and the extraction electrodes 19 and 20 may be formed, for example, using nickel, aluminum, titanium, and the like.

The excitation electrode 15 is an electrode that allows the pair of vibrating arms 10 and 11 to vibrate at a predetermined resonance frequency in a direction moving closer to or away from each other. The first excitation electrode 13 and second excitation electrode 14 that constitute the excitation electrode 15 are patterned and formed on the outer surfaces of the pair of vibrating arms 10 and 11 in an electrically isolated state. Moreover, the first excitation electrode 13 and the second excitation electrode 14 are electrically connected to the mount electrodes 16 and 17 via the extraction electrodes 19 and 20, respectively, on both principal surfaces of the base portion 12.

The mount electrodes 16 and 17 of the present embodiment are laminated films of chromium (Cr) and gold (Au), which are formed by forming a chromium (Cr) film having good adhesion with quartz as a base layer and then forming a thin gold (Au) film on the surface thereof as a finishing layer. However, the present invention is not limited to this, and the mount electrodes 16 and 17 may be formed by forming a chromium film and a nichrome film as a base layer and then forming a thin gold film on the surface thereof as a finishing layer.

The tip ends of the pair of the vibrating arms 10 and 11 are coated with a weight metal film 21 for adjustment (frequency adjustment) of their own vibration states in a manner such as to vibrate within a predetermined frequency range. The weight metal film 21 is divided into a rough tuning film 21a used for tuning the frequency roughly and a fine tuning film 21b used for tuning the frequency finely. By tuning the frequency with the use of the rough tuning film 21a and the fine tuning film 21b, the frequency of the pair of the vibrating arms 10 and 11 can be set to fall within the range of the nominal frequency of the device.

### Package

As shown in FIGS. 1, 3, and 4, the base substrate 2 and the lid substrate 3 are substrates that can be anodically bonded and that are made of a glass material, for example, soda-lime glass, and are formed in a plate-like form. On a bonding surface side of the lid substrate 3 to be bonded to the base substrate 2, a recess portion 3a for a cavity is formed in which the piezoelectric vibrating reed 4 is accommodated.

A bonding film 35 for anodic bonding is formed on the entire surface on the bonding surface side of the lid substrate 3 to be bonded to the base substrate 2. That is to say, the bonding film 35 is formed in a frame region at the periphery of the recess portion 3a for a cavity C in addition to the entire inner surface of the recess portion 3a for a cavity. Although the bonding film 35 of the present embodiment is made of a Si film, the bonding film 35 may be made of aluminum (Al). As will be described later, the bonding film 35 and the base substrate 2 are anodically bonded, whereby the cavity C is vacuum-sealed.

The base substrate 2 is a substrate that is made of a glass material, for example, soda-lime glass, and is formed in an approximately plate-like form having the same outer shape as the lid substrate 3 as shown in FIGS. 1 to 4. More-over, the base substrate 2 is formed with a pair of penetration holes 30 and 31 penetrating through the base substrate 2 in the thickness direction thereof and a pair of penetration electrodes 32 and 33.

As shown in FIGS. 2 and 3, the penetration holes 30 and 31 are formed so as to be received in the cavity C when the piezoelectric vibrator 1 is formed. More specifically, the penetration holes 30 and 31 of the present embodiment are formed such that one penetration hole 30 is positioned at a corresponding position close to the base portion 12 of the mounted piezoelectric vibrating reed 4 which is mounted in a mounting step described later, and the other penetration hole 31 is positioned at a corresponding position close to the tip end sides of the vibrating arms 10 and 11. As shown in FIG. 3, the penetration holes 30 and 31 of the present embodiment are formed so that the inner shape thereof gradually increases from the first surface U side towards the second surface L side.

Next, the penetration electrode will be described. In the following description, although only the penetration electrode 32 is described, the same applies to the penetration electrode 33.

As shown in FIG. 3, the penetration electrode 32 is formed by a cylindrical member 6 made of glass and a conductive member 7 which are disposed at the inner side of the penetration hole 30.

In the present embodiment, the cylindrical member 6 is obtained by baking a paste-like glass frit. The conductive member 7 is disposed at the center of the cylindrical member 6 so as to penetrate through the cylindrical member 6. The cylindrical member 6 is tightly attached to the conductive member 7 and the penetration hole 30. The cylindrical member 6 and the conductive member 7 serve to maintain airtightness of the cavity C by completely blocking the penetration hole 30.

As shown in FIGS. 2 to 4, a pair of lead-out electrodes 36 and 37 is patterned on the first surface U side of the base substrate 2. One lead-out electrode 36 among the pair of lead-out electrodes 36 and 37 is formed so as to be disposed right above one penetration electrode 32. Moreover, the other lead-out electrode 37 is formed so as to be disposed right above the other penetration electrode 33 after being led out from a position near one lead-out electrode 36 towards the tip end sides of the vibrating arms 10 and 11 along the vibrating arms 10 and 11.

Moreover, as shown in FIG. 4, bumps B are formed on the pair of lead-out electrodes 36 and 37. The bumps B are formed of the same gold material as the finishing layer of the mount electrodes. In this way, when the mount electrodes 16 and 17 are bonded to the bumps B by flip-chip bonding, it is possible to sufficiently realize metal diffusion between the mount electrodes 16 and 17 and the bumps B.

The mount electrodes 16 and 17 of the piezoelectric vibrating reed 4 are mounted on the base substrate 2 using the bumps B. In this way, one mount electrode 16 of the piezoelectric vibrating reed 4 is electrically connected to one penetration electrode 32 via one lead-out electrode 36, and the other mount electrode 17 is electrically connected to the other penetration electrode 33 via the other lead-out electrode 37.

Moreover, as shown in FIGS. 1, 3, and 4, a pair of outer electrodes 38 and 39 is formed on the second surface L of the base substrate 2. The pair of outer electrodes 38 and 39 is formed at both ends in the longitudinal direction of the base substrate 2 and is electrically connected to the pair of penetration electrodes 32 and 33, respectively.

When the piezoelectric vibrator 1 configured in this manner is operated, a predetermined driving voltage is applied to the outer electrodes 38 and 39 formed on the base substrate 2. In this way, a current can be made to flow to the excitation electrode 15 including the first and second excitation electrodes 13 and 14, of the piezoelectric vibrating reed 4, and the pair of vibrating arms 10 and 11 is allowed to vibrate at a predetermined frequency in a direction moving closer to or away from each other. This vibration of the pair of vibrating arms 10 and 11 can be used as the time source, the timing source of a control signal, the reference signal source, and the like.

### Piezoelectric Vibrator Manufacturing Method

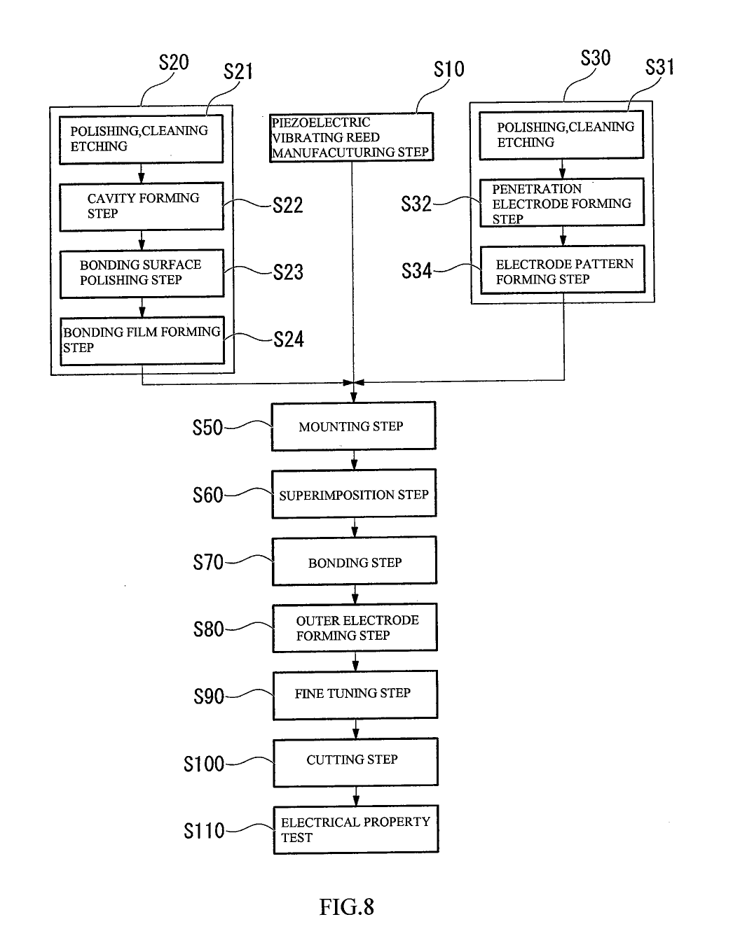

Next, a method of manufacturing the above-described piezoelectric vibrator will be described with reference to a flowchart. FIG. 8 is a flowchart of the manufacturing method of a piezoelectric. The manufacturing method of the piezoelectric vibrator according to the present embodiment mainly includes a piezoelectric vibrating reed manufacturing step S10, a lid substrate wafer manufacturing step S20, a base substrate wafer manufacturing step S30, and an assembling step (S50 and subsequent steps). Among these steps, the piezoelectric vibrating reed manufacturing step S10, the lid substrate wafer manufacturing step S20, and the base substrate wafer manufacturing step S30 can be performed in parallel.

### First Embodiment

### Piezoelectric Vibrating Reed Manufacturing Step

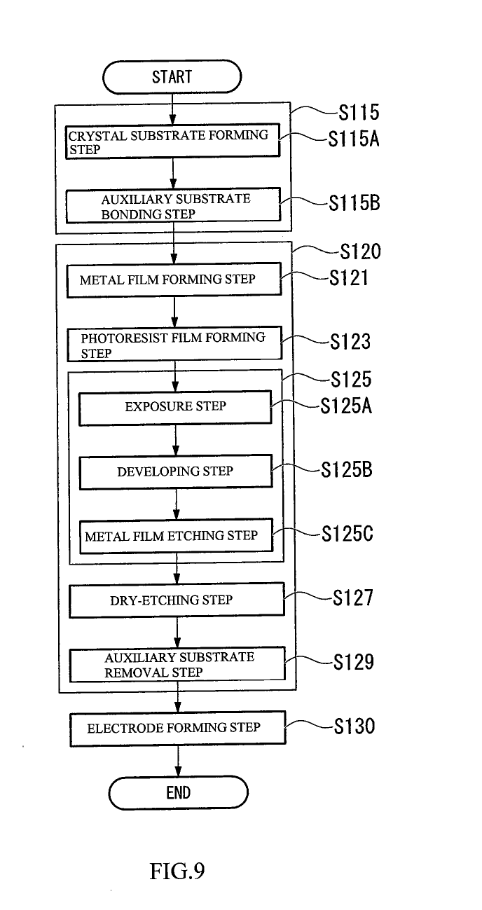

FIG. 9 is a flowchart of a piezoelectric vibrating reed manufacturing step S10. The piezoelectric vibrating reed manufacturing step S10 mainly includes a crystal substrate preparation step S115, a piezoelectric vibrating reed outer shape forming step S120, and an electrode forming step S130.

### Crystal Substrate Preparation Step: Crystal Substrate Forming Step

The crystal substrate preparation step S115 includes a crystal substrate forming step S115A and an auxiliary substrate bonding step S115B. In the crystal substrate forming step S115A, a crystal substrate (wafer) having a predetermined thickness (about 100 μm in the present embodiment) is formed. Specifically, first, a rough crystal Lambert is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a crystal substrate having a thickness of about 100 μm.

### Crystal Substrate Preparation Step: Auxiliary Substrate Bonding Step

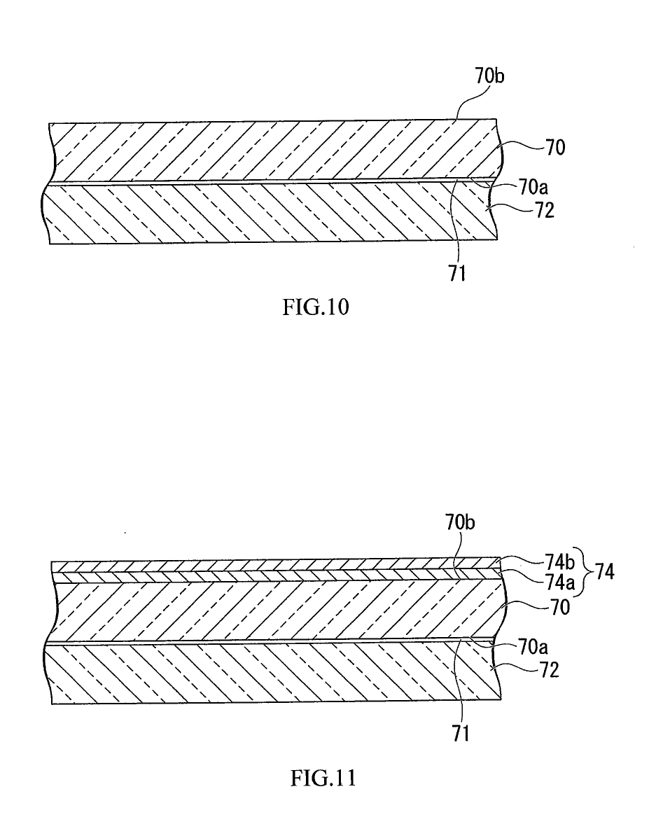

FIG. 10 illustrates an auxiliary substrate bonding step according to the present embodiment. In the following description, it is assumed that a bonding surface of the crystal substrate 70 to be bonded to an auxiliary substrate is a first surface 70a, and the opposite surface thereof is a second surface 70b.

Subsequently, as shown in FIG. 10, an auxiliary substrate bonding step S115B is performed where the crystal substrate 70 and the auxiliary substrate 72 is bonded.

The auxiliary substrate 72 is formed of a material containing a silicon oxide as its main component and has approximately the same etching rate as the crystal substrate 70. In the present embodiment, a glass is used as the material of the auxiliary substrate 72. Moreover, a crystal may be used as the material of the auxiliary substrate 72. By doing so, it is possible to make the etching rates of the crystal substrate 70 and the auxiliary substrate 72 approximately the same and to make the linear expansion coefficients of the crystal substrate 70 and the auxiliary substrate 72 approximately the same. The auxiliary substrate 72 has an outer shape slightly larger than the crystal substrate 70. Therefore, it is possible to bond the crystal substrate 70 and the auxiliary substrate 72 in a state where the entire bonding surface of the crystal substrate 70 to be bonded to the auxiliary substrate 72 is covered with the auxiliary substrate 72.

In the present embodiment, the crystal substrate 70 and the auxiliary substrate 72 are bonded by anodic bonding. Specifically, the anodic bonding is performed in the following order.

First, an anodic bonding film 71 made of a metal such as aluminum or chromium is formed on the entire region of the first surface 70a of the crystal substrate 70. The anodic bonding film 71 is formed to a thickness of about 0.1 μm, for example. The anodic bonding film 71 can be performed by a deposition method such as a sputtering method or a CVD method.

Subsequently, the crystal substrate 70 and the auxiliary substrate 72 are superimposed onto each other with the anodic bonding film 71 disposed therebetween. Then, a positive electrode is connected to the first substrate 70a of the crystal substrate 70, and a negative electrode is connected to the outer side of the auxiliary substrate 72. The positive electrode may be connected to the second surface 70b of the crystal substrate 70, and the negative electrode may be connected to the outer side of the auxiliary substrate 72.

Subsequently, a voltage of about 500 V is applied between the respective electrodes while heating the crystal substrate 70 and the auxiliary substrate 72 to a temperature of about 400° C., for example. In this way, the crystal substrate 70 and the auxiliary substrate 72 can be anodically bonded. Since mirror processing is performed in the crystal substrate forming step S115A, the flatness of the surface of the first surface 70a can be secured, and stable bonding with the auxiliary substrate 72 can be achieved.

The crystal substrate preparation step S115 ends at a point in time when the crystal substrate 70 and the auxiliary substrate 72 are anodically bonded.

### Piezoelectric Vibrating Reed Outer Shape Forming Step

Subsequently, a piezoelectric vibrating reed outer shape forming step S120 is performed where the outer shape of the piezoelectric vibrating reed is formed from the crystal substrate 70. The piezoelectric vibrating reed outer shape forming step S120 mainly includes: a metal film forming step S121 of forming a metal film later serving as a metal mask for dry-etching; a photoresist film forming step S123 of forming a photoresist film on the metal film; a resist pattern forming step S125 of forming a resist pattern from the photoresist film; a dry-etching step S127 of etching the crystal substrate 70; and an auxiliary substrate removal step S129 of removing the auxiliary substrate 72 from the crystal substrate 70.

FIG. 11 illustrates a metal film forming step.

In the piezoelectric vibrating reed outer shape forming step S120, first, as shown in FIG. 11, a metal film forming step S121 is performed where a mask metal film 74 is deposited on the second surface 70b of the crystal substrate 70. The mask metal film 74 is a laminated film, for example, including a base film 74a made of chromium and a protection film 74b made of gold, and the respective films are formed by a sputtering method or a deposition method.

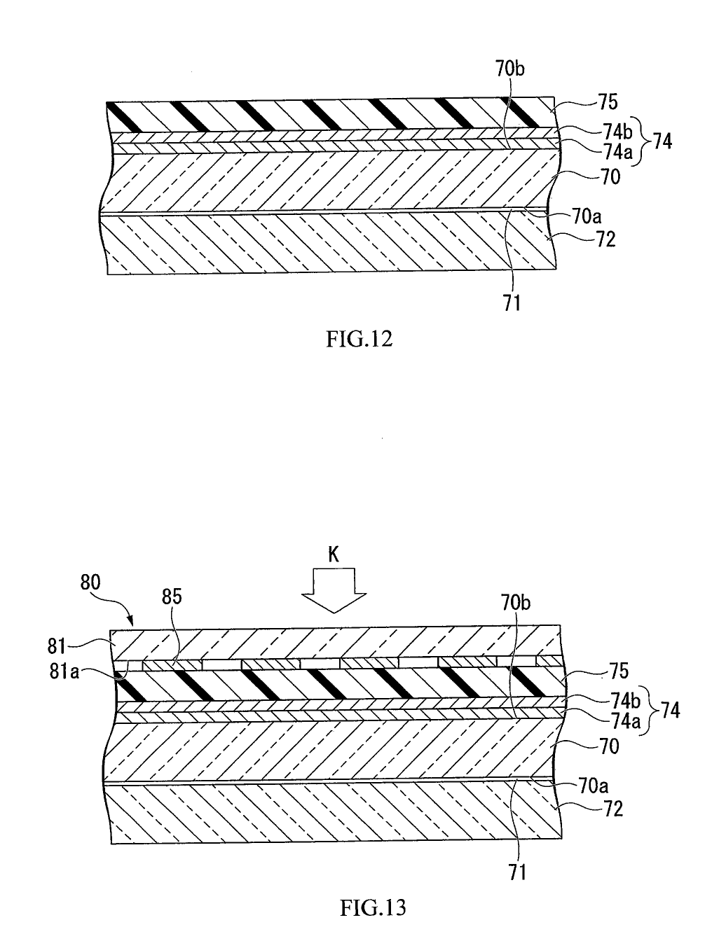

FIG. 12 illustrates a photoresist film forming step.

Subsequently, as shown in FIG. 12, a photoresist film forming step S123 is performed where a photoresist film 75 is formed on the mask metal film 74. Specifically, a resist material is applied on the mask metal film 74 by a spin coating method, and the resist material is pre-baked to evaporate an organic solvent, whereby the photoresist film 75 is formed.

FIG. 13 illustrates a resist pattern forming step.

Subsequently, as shown in FIG. 13, a resist pattern forming step S125 is performed where a resist pattern is formed on the photoresist film 75 using a photolithographic technique. Although a method of forming a resist pattern includes a method of forming a positive resist pattern and a method of forming a negative resist pattern, in the present embodiment, the case of forming a negative resist pattern will be described as an example.

In the resist pattern forming step S125, first, as shown in FIG. 13, an exposure step S125A of exposing the photoresist film 75 is performed. A photomask 80 has a structure in which a light-blocking film pattern 85 made of chromium or the like is formed on a principal surface 81a of a light-transmitting photosensitive substrate 81 made of a glass or the like. The light-blocking film pattern 85 is for patterning the photoresist film 75 and is formed on a region of the principal surface 81a of the photosensitive substrate 81 excluding a region corresponding to the outer shape of the piezoelectric vibrating reed.

In the exposure step S125A, first, the photomask 80 is set on the photoresist film 75 so that the principal surface 81a side faces the photoresist film 75. At that time, the photomask 80 is set in a state where the crystal substrate 70 and the photomask 80 are positionally aligned. Subsequently, a UV beam K is irradiated. In this way, the UV beam K passes through the photomask 80 and the photoresist film 75 is exposed. Here, the photoresist film 75 in the exposed region is cured. When the exposure is finished, the photomask 80 is removed.

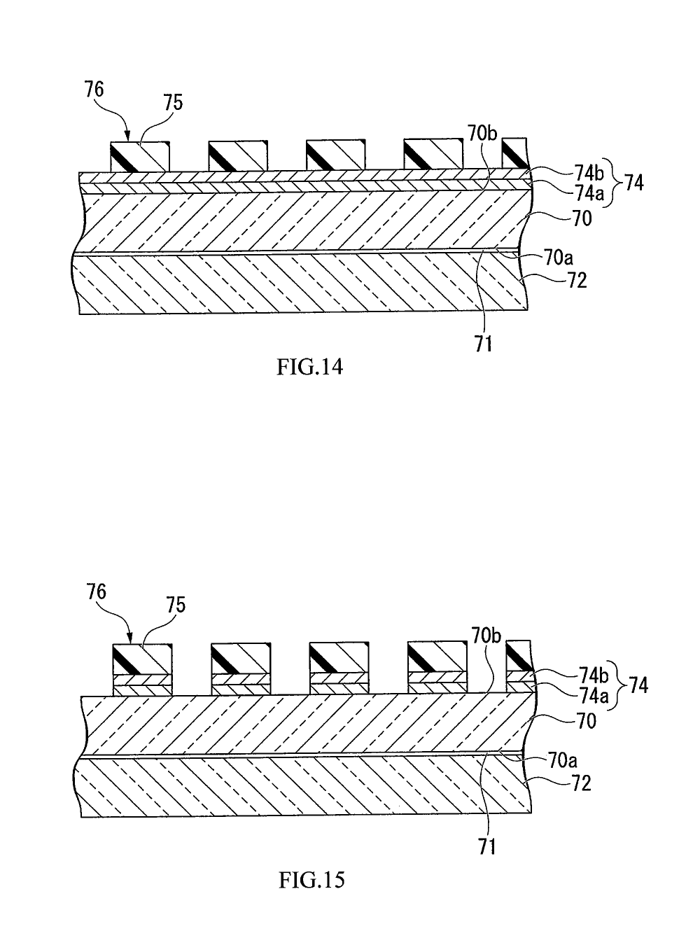

FIG. 14 illustrates a developing step.

Subsequently, as shown in FIG. 14, a developing step S125B of developing the photoresist film 75 is performed. Specifically, the crystal substrate 70 is dipped into a developing solution, whereby only a region of the photoresist film 75 which is not exposed by the UV beam K is selectively removed. On the mask metal film 74 after developing, a plurality of resist patterns 76 is formed in a state such that the photoresist film 75 remains in a shape corresponding to the outer shape of the piezoelectric vibrating reed.

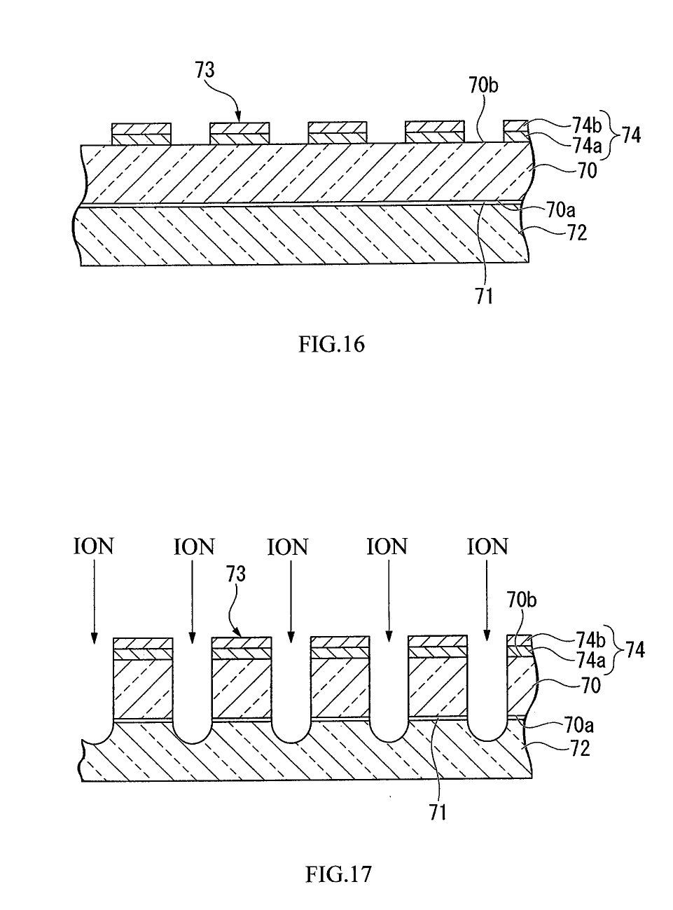

FIG. 15 illustrates a metal film etching step.

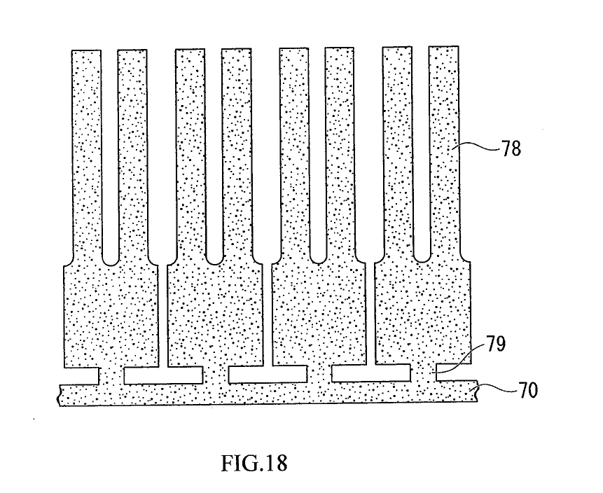

FIG. 16 illustrates the removal of the resist pattern.

Subsequently, as shown in FIG. 15, a metal film etching step S125C is performed where etching is performed using the resist patterns 76 as a mask. In this step, a metal film which is not masked by the resist pattern 76 is selectively removed. After that, the resist patterns 76 of the photoresist film 75 are removed. In this way, as shown in FIG. 16, an outer shape pattern 73 of a metal film serving as a metal mask for dry-etching is formed on the second surface 70b of the crystal substrate 70.

FIG. 17 illustrates a dry-etching step.

Subsequently, as shown in FIG. 17, a dry-etching step S127 is performed where the crystal substrate 70 is dry-etched using the patterned outer shape pattern 73 as a mask.

As a specific dry-etching method, first, the crystal substrate 70 bonded to the auxiliary substrate 72 is transferred into a vacuum chamber (not shown) and set on a cooling plate (not shown). Subsequently, an etching gas is introduced into the vacuum chamber. The etching gas is a mixed gas in which an argon gas or the like is added to a sulfur hexafluoride or a carbon tetrafluoride gas. After that, a predetermined pressure atmosphere is created in the vacuum chamber, and plasma is generated in the vacuum chamber by a plasma generation device (not shown), whereby active species of ions or the like are generated from the etching gas. The active species are caused to collide with the first surface 70a of the crystal substrate 70 and react with silicon atoms contained in the crystal substrate 70, whereby dry-etching is achieved.

In the present embodiment, as shown in FIG. 17, dry-etching starts from the second surface 70b of the crystal substrate 70 and penetrates through the first surface 70a, and successively, the auxiliary substrate 72 made of a glass is dry-etched.

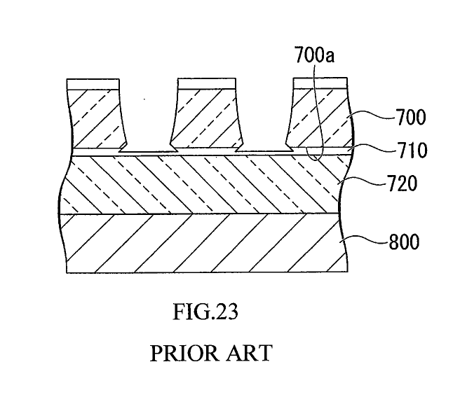

In general, the dry-etching is more likely to progress in a portion distant from the mask than in the vicinity of the mask. In the method of the related art, as shown in FIG. 23, the silicon substrate 720 is attached to one surface of the crystal substrate 700 by the adhesive 710, and the etching stops at the point in time when the etching reaches the adhesive 710. When etching stops in such a manner rather than over-etching is achieved, the side surfaces of a hole formed by the etching is not sufficiently etched, and it is unable to form the side surfaces of the hole to be vertical to the principal surface.

However, in the present embodiment, as shown in FIG. 17, since etching is performed so as to penetrate through the first surface 70a, and successively, the auxiliary substrate 72 is over-etched, it is possible to sufficiently etch the side surfaces of the hole and to form the side surfaces of the hole to be vertical to the principal surface.

Moreover, in the method of the related art, as shown in FIG. 23, since the thickness of the adhesive 710 is as thick as about 100 μm, when the etching reaches the adhesive 710 while penetrating through the crystal substrate 700, side-etching progresses along an interface between the crystal substrate 700 and the adhesive 710. Therefore, the protection of the adhesion surface 700a between the crystal substrate 700 and the adhesive 710 is weekend, and the adhesion surface 700a is etched.

However, in the present embodiment, as shown in FIG. 17, the crystal substrate 70 and the auxiliary substrate 72 are anodically bonded with the anodic bonding film 71 disposed therebetween. Since the anodic bonding film 71 is made of aluminum or chromium, and the etching rate of the anodic bonding film 71 is higher than the etching rate of the crystal substrate 70, side-etching of the anodic bonding film 71 is hard to progress. Therefore, it is possible to suppress the first surface 70a of the crystal substrate 70 from being etched. On the other hand, since the anodic bonding film 71 is very thin, the dry-etching progresses without stopping at the anodic bonding film 71. Therefore, it is possible to perform over-etching so as to penetrate through the crystal substrate 70. In this way, it is possible to form the outer shape of the piezoelectric vibrating reed with higher accuracy.

FIG. 18 illustrates a crystal substrate after the dry-etching.

As described above, through the dry-etching step S127, a region which is not masked is selectively removed. As a result, as shown in FIG. 18, it is possible to form piezoelectric substrates 78 having the outer shape of the piezo-electric vibrating reed. The respective piezoelectric substrates 78 are connected to the crystal substrate 70 after the dry-etching.

Subsequently, an auxiliary substrate removal step S129 of removing the auxiliary substrate 72 from the crystal substrate 70 is performed. Specifically, after the auxiliary substrate 72 is grinded to a predetermined thickness, the auxiliary substrate 72 and the anodic bonding film 71 are removed by wet-etching or the like. The crystal substrate 70 and the auxiliary substrate 72 may be separated by removing the anodic bonding film 71 by wet-etching or the like. In this way, the piezoelectric vibrating reed outer shape forming step S120 ends.

Subsequently, an electrode forming step S130 is performed where electrodes and the like are formed on the outer surface of the piezoelectric substrate 78 having the outer shape of the piezoelectric vibrating reed.

In the electrode forming step S130, first, a metal film is formed and patterned on the piezoelectric substrate 78, thus forming the excitation electrodes, the extraction electrodes, the mount electrodes, and the weight metal film. Subsequently, rough tuning of the resonance frequency of the piezoelectric substrate 78 is performed. This rough tuning is achieved by irradiating the rough tuning film of the weight metal film with a laser beam to evaporate a part of the rough tuning film, thus changing the weight thereof. In this way, the electrode forming step S130 ends.

Finally, connection portions 79 between the respective piezoelectric substrates 78 and the crystal substrate 70 are cut to obtain individual fragmented piezoelectric vibrating reeds, and at this point in time, the piezoelectric vibrating reed manufacturing step S10 ends.

### Lid Substrate Wafer Manufacturing Step

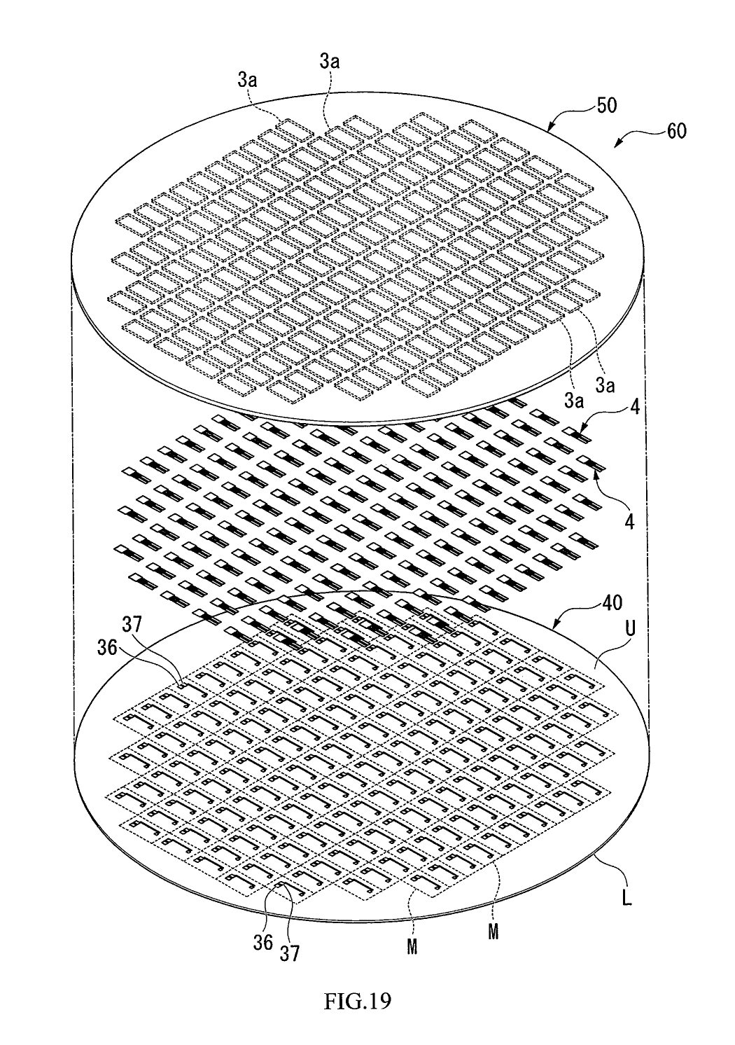

FIG. 19 is an exploded perspective view of a wafer assembly. The dotted line shown in FIG. 19 is a cutting line M along which a cutting step performed later is achieved.

In the lid substrate wafer manufacturing step S20, as shown in FIG. 19, the lid substrate wafer 50 later serving as the lid substrate is manufactured. First, a disk-shaped lid substrate wafer 50 made of a soda-lime glass is polished to a pre-determined thickness and cleaned, and then, the affected uppermost layer is removed by etching or the like (S21). Subsequently, in a cavity forming step S22, a plurality of recess portions 3a for cavities is formed on a bonding surface of the lid substrate wafer 50 to be bonded to the base substrate wafer 40. The recess portions 3a for cavities are formed by heat-press molding, etching, or the like. After that, in a bonding surface polishing step S23, the bonding surface bonded to the base substrate wafer 40 is polished.

Subsequently, in a bonding film forming step S24, a bonding film 35 shown in FIGS. 1, 2, and 4 is formed on the bonding surface to be bonded to the base substrate wafer 40. The bonding film 35 may be formed on the entire inner surface of the cavity C in addition to the bonding surface to be bonded to the base substrate wafer 40. In this way, patterning of the bonding film 35 is not necessary, and the manufacturing cost can be reduced. The bonding film 35 can be formed by a film-formation method such as sputtering or CVD. Since the bonding surface polishing step S23 is performed before the bonding film forming step S24, the flatness of the surface of the bonding film 35 can be secured, and stable bonding with the base substrate wafer 40 can be achieved.

### Base Substrate Wafer Manufacturing Step

In a base substrate wafer manufacturing step S30, as shown in FIG. 19, the base substrate wafer 40 later serving as the base substrate is manufactured. First, a disk-shaped base substrate wafer 40 made of a soda-lime glass is polished to a predetermined thickness and cleaned, and then, the affected uppermost layer is removed by etching or the like (S31).

### Penetration Electrode Forming Step

Subsequently, a penetration electrode forming step S32 is performed where the pair of penetration electrodes 32 and 33 is formed on the base substrate wafer 40. Hereinafter, the penetration electrode forming step S32 will be described. In the following description, although only the step of forming the penetration electrode 32 is described, the same applies to the step of forming the penetration electrode 33.

First, penetration holes 30 shown in FIG. 3 are formed in the base substrate wafer 40 by performing press working or the like in a direction from the second surface L towards the first surface U. Subsequently, the conductive member 7 is inserted into the penetration holes 30 and a paste material made of glass frit is filled therein. After that, the paste material is baked so that the cylindrical member 6 made of glass, the penetration holes 30, and the conductive member 7 shown in FIG. 3 are integrated with each other. Finally, both the first surface U and the second surface L of the base substrate wafer 40 are polished to obtain a flat surface while exposing the conductive member 7 to both the first surface U and the second surface L, whereby the penetration electrodes 32 are formed in the penetration holes 30. With the penetration electrodes 32, electrical connection between the first surface U side and the second surface L side of the base substrate wafer 40 is secured, and airtightness of the cavity C can be secured.

### Electrode Pattern Forming Step

Subsequently, as shown in FIGS. 4 and 19, an electrode pattern forming step S34 is performed where the lead-out electrodes 36 and 37 are formed on the first surface U of the base substrate wafer 40. In the present embodiment, since the lead-out electrodes 36 and 37 are made of the same material, it is possible to form the lead-out electrodes 36 and 37 at the same time. The lead-out electrodes 36 and 37 are formed by patterning a coating formed by a sputtering method, a vacuum deposition method, or the like using a photolithography technique.

Moreover, as shown in FIG. 4, a pair of bumps B is formed on the pair of lead-out electrodes 36 and 37. The bumps B are formed using a wire bonder. Specifically, the tip end of an ultrafine gold wire is welded by arc discharging or the like, and a gold ball is formed on the tip end of the gold wire. Subsequently, the gold ball at the tip end of the gold wire are bonded to the bump formation positions on the lead-out electrodes 36 and 37 by applying ultrasonic vibration while pressing the gold ball against the bumps. Finally, the gold wire is pulled and cut, whereby the tapered bumps B are formed. In FIG. 19, for better understanding of the drawing, illustrations of the bumps are omitted. The base substrate wafer manufacturing step S30 ends at this point in time.

### Piezoelectric Vibrator Assembling Step Subsequent To Mounting Step S50

Subsequently, a mounting step S50 is performed where the piezo-electric vibrating reeds 4 are bonded to the lead-out electrodes 36 and 37 of the base substrate wafer 40 by the bumps B. Specifically, first, the bumps B are heated to a predetermined temperature. Subsequently, the base portions 12 of the piezoelectric vibrating reeds 4 are placed on the bumps B, and an ultrasonic vibration is applied while pressing the piezoelectric vibrating reeds 4 against the bumps B. In this way, as shown in FIG. 3, the base portions 12 are mechanically fixed to the bumps B in a state where the vibrating arms 10 and 11 of the piezo-electric vibrating reed 4 are floated from the first surface U of the base substrate wafer 40. Moreover, the mount electrodes 16 and 17 are electrically connected to the lead-out electrodes 36 and 37.

After the mounting of the piezoelectric vibrating reed 4 is completed, as shown in FIG. 19, a superimposition step S60 is performed where the lid substrate wafer 50 is superimposed onto the base substrate wafer 40. Specifically, the two wafers 40 and 50 are aligned at a correct position using reference marks (not shown) or the like as indices. In this way, the piezoelectric vibrating reed 4 mounted on the base substrate wafer 40 is accommodated in the cavity C which is surrounded by the recess portion 3a for cavities of the lid substrate wafer 50 and the base substrate wafer 40.

After the superimposition step S60 is performed, a bonding step S70 is performed where the two superimposed wafers 40 and 50 are inserted into an anodic bonding machine (not shown) to achieve anodic bonding under a predetermined temperature atmosphere with application of a predetermined voltage. Specifically, a predetermined voltage is applied between the bonding film 35 and the base substrate wafer 40. Then, an electrochemical reaction occurs at an interface between the bonding film 35 and the base substrate wafer 40, whereby they are closely and tightly adhered and anodically bonded. In this way, the piezoelectric vibrating reed 4 can be sealed in the cavity C, and a wafer assembly 60 in which the base substrate wafer 40 and the lid substrate wafer 50 are bonded to each other can be obtained as shown in FIG. 10. In FIG. 19, for better understanding of the drawing, the wafer assembly 60 is illustrated in an exploded state, and illustration of the bonding film 35 is omitted from the lid substrate wafer 50.

Subsequently, an outer electrode forming step S80 is performed where a conductive material is patterned onto the second surface L of the base substrate wafer 40 so as to form a plurality of pairs of outer electrodes 38 and 39 (see FIG. 3) which is electrically connected to the pair of penetration electrodes 32 and 33. Through this step, the piezoelectric vibrating reed 4 is electrically connected to the outer electrodes 38 and 39 through the penetration electrodes 32 and 33.

Subsequently, a fine tuning step S90 is performed on the wafer assembly 60 where the frequencies of the individual piezoelectric vibrators sealed in the cavities C are tuned finely to fall within a predetermined range. Specifically, a predetermined voltage is continuously applied to the outer electrodes 38 and 39 shown in FIG. 4 to allow the piezoelectric vibrating reeds 4 to vibrate, and the vibration frequency is measured. In this state, a laser beam is irradiated onto the base substrate wafer 40 from the outer side so as to evaporate the fine tuning film 21b of the weight metal film 21 shown in FIGS. 5 and 6. In this way, since the weight on the tip end sides of the pair of vibrating arms 10 and 11 decreases, the frequency of the piezoelectric vibrating reed 4 increases. By so doing, the frequency of the piezoelectric vibrator can be finely tuned so as to fall within the range of the nominal frequency.

After the fine tuning of the frequency is completed, a cutting step S100 is performed where the bonded wafer assembly 60 is cut along the cutting line M shown in FIG. 19. Specifically, first, a UV tape is attached on the surface of the base substrate wafer 40 of the wafer assembly 60. Subsequently, a laser beam is irradiated along the cutting line M from the side of the lid substrate wafer 50 (scribing). Subsequently, the wafer assembly 60 is divided and cut along the cutting line M by a cutting blade pressing against the surface of the UV tape (breaking). After that, the UV tape is separated by irradiation of UV light. In this way, it is possible to divide the wafer assembly 60 into a plurality of piezoelectric vibrators. The wafer assembly 60 may be cut by other methods such as dicing.

Moreover, the fine adjustment step S90 may be performed after cutting the wafer body into pieces of individual piezoelectric vibrators in the cutting step S100. However, as described above, the fine adjustment can be performed in a state of the wafer body 60 by performing the fine adjustment step S90 first. Therefore, in the case of performing the fine adjustment step S90 first, a plurality of piezoelectric vibrators can be finely adjusted more efficiently. This is preferable since the throughput can be improved.

Then, an inner electrical property test S110 is performed. That is, resonance frequency, resonant resistance value, drive level characteristics (exciting power dependency of resonance frequency and resonant resistance value), and the like of the piezoelectric vibrating reed 4 are checked by measurement. Moreover, an insulation resistance characteristic and the like are checked together. Finally, visual inspection of the piezoelectric vibrator is performed to finally check the dimension, quality, and the like. Thus, the manufacturing of the piezoelectric vibrator ends.

According to the present embodiment, since the auxiliary substrate 72 having approximately the same etching rate as the crystal substrate 70 is bonded to the crystal substrate 70, etching will not penetrate through the auxiliary substrate 72 immediately. Moreover, by successively dry-etching the crystal substrate 70 and the auxiliary substrate 72, it is possible to perform over-etching so as to penetrate through the crystal substrate 70. In this way, since the side surfaces of a hole formed by the etching can be processed to be vertical to a principal surface, it is possible to form the outer shape of the piezoelectric vibrating reed with high accuracy.

Moreover, in the present embodiment, the crystal substrate 70 and the auxiliary substrate 72 are anodically bonded. Since the anodic bonding film 71 is made of aluminum, chromium, or the like, and the etching rate of the anodic bonding film 71 is higher than the etching rate of the crystal substrate 70, side-etching of the anodic bonding film 71 is hard to progress. Therefore, according to this configuration, it is possible to suppress the first surface 70a of the crystal substrate 70 from being etched. On the other hand, since the anodic bonding film 71 is very thin, the dry-etching progresses without stopping at the anodic bonding film 71. Therefore, it is possible to perform over-etching so as to penetrate through the crystal substrate 70. In this way, it is possible to form the outer shape of the piezoelectric vibrating reed with higher accuracy.

### Second Embodiment

### Case Where Crystal Substrate and Auxiliary Substrate are Hydrogen-Bonded

In the first embodiment, the crystal substrate and the auxiliary substrate are anodically bonded. However, the present embodiment is different from the first embodiment in that the crystal substrate and the auxiliary substrate are hydrogen-bonded. The detailed description of the same configurations as the first embodiment will be omitted.

In the present embodiment, the crystal substrate and the auxiliary substrate are bonded by hydrogen bonding. Specifically, hydrogen bonding is performed in the following order.

First, a thin oxide film is formed on the respective bonding surfaces of the crystal substrate and the auxiliary substrate. At the same time, a hydrophilic treatment of attaching a hydroxy group to the respective bonding surfaces is per-formed. Subsequently, the respective bonding surfaces of the crystal substrate and the auxiliary substrate are superimposed onto each other. At that time, the hydrophilic bonding surfaces of the crystal substrate and auxiliary substrate are brought into close contact with each other due to the hydrogen bond between the hydroxy groups. After that, the crystal substrate and the auxiliary substrate are heated so as to eliminate hydrogen. In this way, the crystal substrate and the auxiliary substrate are hydrogen-bonded.

When the crystal substrate and the auxiliary substrate are hydrogen-bonded, the crystal substrate and the auxiliary substrate can be seamlessly hydrogen-bonded by a hydrogen bond without using an adhesive or a bonding film. Therefore, the present embodiment is superior to the first embodiment, in that over-etching can be performed more securely so as to penetrate through the crystal substrate while preventing the first surface of the crystal substrate from being etched.

On the other hand, since the heat treatment temperature of the anodic bonding in the first embodiment is about 400° C. whereas the heat treatment temperature of the hydrogen bonding is generally high, the heat treatment temperature of the anodic bonding in the first embodiment is low. Therefore, the first embodiment is superior to the present embodiment in that the crystal substrate is less thermally damaged.

### Third Embodiment

### Case Where Crystal Substrate and Auxiliary Substrate 72 are Bonded at Room Temperature

In the first embodiment, the crystal substrate and the auxiliary substrate are anodically bonded. Moreover, in the second embodiment, the crystal substrate and the auxiliary substrate are hydrogen-bonded. However, the present embodiment is different from the first and second embodiments in that the crystal substrate and the auxiliary substrate are bonded at a room temperature. The detailed description of the same configurations as the first and second embodiments will be omitted.

In the present embodiment, the crystal substrate and the auxiliary substrate are bonded by room-temperature bonding. Specifically, the room-temperature bonding is performed in the following order.

First, argon ions or the like are irradiated to the respective bonding surfaces of the crystal substrate and the auxiliary substrate under a high-vacuum atmosphere. By the ion bombardment effect, organic materials physically or chemically adsorbed on the surface are removed, and a highly clean and activated atmosphere is created. After that, the crystal substrate and the auxiliary substrate are closely attached and bonded under a high-vacuum atmosphere in which contaminants are not adsorbed again on the uppermost surface. In this way, bonding with excellent strength can be achieved under the room temperature.

In the present embodiment, the crystal substrate and the auxiliary substrate can be seamlessly bonded similarly to the second embodiment. Therefore, the present embodiment is superior to the first embodiment, in that over-etching can be performed more securely so as to penetrate through the crystal substrate while preventing the first surface of the crystal substrate from being etched.

Moreover, in the present embodiment, the crystal substrate and the auxiliary substrate can be bonded at the room temperature without performing a heat treatment. Therefore, the present embodiment is superior to the first and second embodiments in that the crystal substrate and the auxiliary substrate can be bonded without impairing the characteristics of the crystal substrate.

Moreover, in the present embodiment, since bonding is achieved under the room temperature, it is not necessary to consider the linear expansion coefficient of the auxiliary substrate. Therefore, the present embodiment is superior to the first and second embodiments in that it is possible to choose a cheap auxiliary substrate and to decrease the manufacturing cost.

### Oscillator

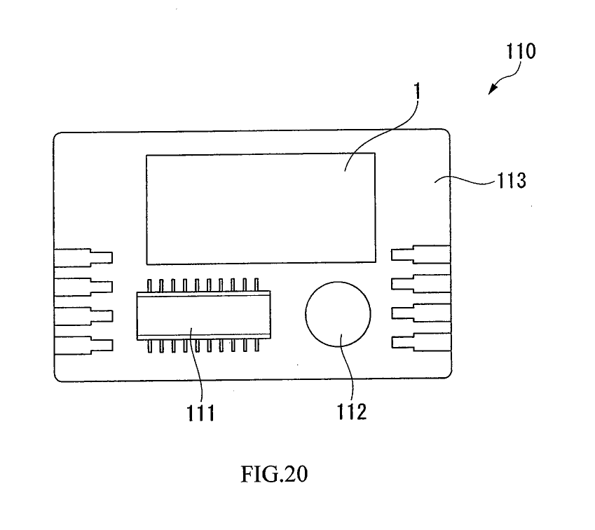

Next, an oscillator according to another embodiment of the invention will be described with reference to FIG. 20.

In an oscillator 110 according to the present embodiment, the piezo-electric vibrator 1 is used as a vibrator electrically connected to an integrated circuit 111, as shown in FIG. 20. The oscillator 110 includes a substrate 113 on which an electronic component 112, such as a capacitor, is mounted. The integrated circuit 111 for an oscillator is mounted on the substrate 113, and the piezoelectric vibrating reed of the piezoelectric vibrator 1 is mounted near the integrated circuit 111. The electronic component 112, the integrated circuit 111, and the piezoelectric vibrator 1 are electrically connected to each other by a wiring pattern (not shown). In addition, each of the constituent components is molded with a resin (not shown).

In the oscillator 110 configured as described above, when a voltage is applied to the piezoelectric vibrator 1, the piezoelectric vibrating reed in the piezoelectric vibrator 1 vibrates. This vibration is converted into an electrical signal due to the piezoelectric property of the piezoelectric vibrating reed and is then input to the integrated circuit 111 as the electrical signal. The input electrical signal is subjected to various kinds of processing by the integrated circuit 111 and is then output as a frequency signal. In this way, the piezoelectric vibrator 1 functions as an oscillator.

Moreover, by selectively setting the configuration of the integrated circuit 111, for example, an RTC (real time clock) module, according to the demands, it is possible to add a function of controlling the operation date or time of the corresponding device or an external device or of providing the time or calendar in addition to a single functional oscillator for a clock.

Since the oscillator 110 according to the present embodiment includes the piezoelectric vibrator 1 having excellent performance, it is possible to provide the oscillator 110 having excellent performance.

### Electronic Device

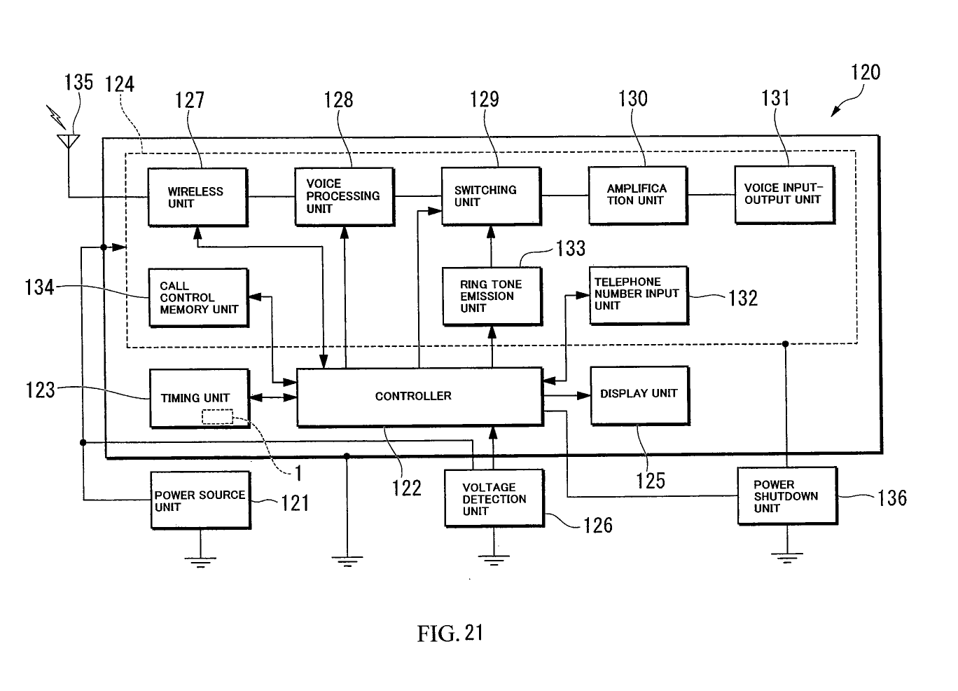

Next, an electronic device according to another embodiment of the invention will be described with reference to FIG. 21. In addition, a portable information device 120 including the piezoelectric vibrator 1 will be described as an example of an electronic device. The portable information device 120 according to the present embodiment is represented by a mobile phone, for example, and has been developed and improved from a wristwatch in the related art. The portable information device 120 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built in an inner portion of the band. However, the portable information device 120 is very small and light compared with a mobile phone in the related art.

Next, the configuration of the portable information device 120 according to the present embodiment will be described. As shown in FIG. 21, the portable information device 120 includes the piezoelectric vibrator 1 and a power supply section 121 for supplying power. The power supply section 121 is formed of a lithium secondary battery, for example. A control section 122 which per-forms various kinds of control, a clock section 123 which performs counting of time and the like, a communication section 124 which performs communication with the outside, a display section 125 which displays various kinds of information, and a voltage detecting section 126 which detects the voltage of each functional section are connected in parallel to the power supply section 121. In addition, the power supply section 121 supplies power to each functional section.

The control section 122 controls an operation of the entire system. For example, the control section 122 controls each functional section to transmit and receive the audio data or to measure or display a current time. In addition, the control section 122 includes a ROM in which a program is written in advance, a CPU which reads and executes a program written in the ROM, a RAM used as a work area of the CPU, and the like.

The clock section 123 includes an integrated circuit, which has an oscillation circuit, a register circuit, a counter circuit, and an interface circuit therein, and the piezoelectric vibrator 1. When a voltage is applied to the piezo-electric vibrator 1, the piezoelectric vibrating reed vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 122 through the interface circuit, and current time, current date, calendar information, and the like are displayed on the display section 125.

The communication section 124 has the same function as a mobile phone in the related art, and includes a wireless section 127, an audio processing section 128, a switching section 129, an amplifier section 130, an audio input/output section 131, a telephone number input section 132, a ring tone generating section 133, and a call control memory section 134.

The wireless section 127 transmits/receives various kinds of data, such as audio data, to/from the base station through an antenna 135. The audio processing section 128 encodes and decodes an audio signal input from the wireless section 127 or the amplifier section 130. The amplifier section 130 amplifies a signal input from the audio processing section 128 or the audio input/output section 131 up to a predetermined level. The audio input/output section 131 is formed by a speaker, a microphone, and the like, and amplifies a ring tone or incoming sound louder or collects the sound.

In addition, the ring tone generating section 133 generates a ring tone in response to a call from the base station. The switching section 129 switches the amplifier section 130, which is connected to the audio processing section 128, to the ring tone generating section 133 only when a call arrives, so that the ring tone generated in the ring tone generating section 133 is output to the audio input/output section 131 through the amplifier section 130.

In addition, the call control memory section 134 stores a program related to incoming and outgoing call control for communications. Moreover, the telephone number input section 132 includes, for example, numeric keys from 0 to 9 and other keys. The user inputs a telephone number of a communication destination by pressing these numeric keys and the like.

The voltage detecting section 126 detects a voltage drop when a voltage, which is applied from the power supply section 121 to each functional section, such as the control section 122, drops below the predetermined value, and notifies the control section 122 of the detection. In this case, the predetermined voltage value is a value which is set beforehand as the lowest voltage necessary to operate the communication section 124 stably. For example, it is about 3 V. When the voltage drop is notified from the voltage detecting section 126, the control section 122 disables the operation of the wireless section 127, the audio processing section 128, the switching section 129, and the ring tone generating section 133. In particular, the operation of the wireless section 127 that consumes a large amount of power should be necessarily stopped. In addition, a message informing that the communication section 124 is not available due to insufficient battery power is displayed on the display section 125.

That is, it is possible to disable the operation of the communication section 124 and display the notice on the display section 125 by the voltage detecting section 126 and the control section 122. This message may be a character message. Or as a more intuitive indication, a cross mark (X) may be displayed on a telephone icon displayed at the top of the display screen of the display section 125.

In addition, the function of the communication section 124 can be more reliably stopped by providing a power shutdown section 136 capable of selectively shutting down the power of a section related to the function of the communication section 124.

Since the portable information device 120 according to the present embodiment includes the piezoelectric vibrator 1 having excellent performance, it is possible to provide the portable information device 120 having excellent performance.

### Radio-Controlled Timepiece

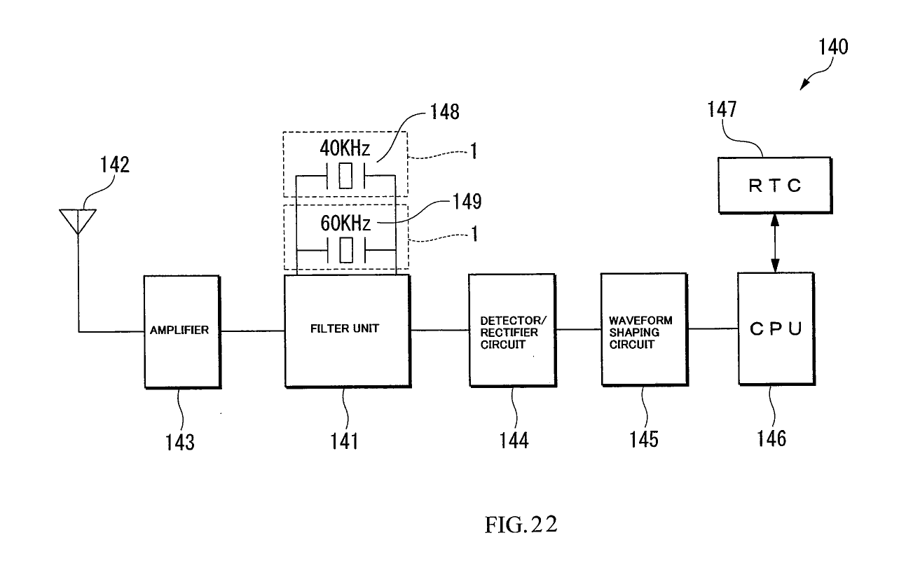

Next, a radio-controlled timepiece according to still another embodiment of the invention will be described with reference to FIG. 22.

As shown in FIG. 22, a radio-controlled timepiece 140 according to the present embodiment includes the piezoelectric vibrators 1 electrically connected to a filter section 141. The radio-controlled timepiece 140 is a clock with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionosphere and the land surface, and therefore has a propagation range wide enough to cover the entire area of Japan through the two transmission centers.

Hereinafter, the functional configuration of the radio-controlled time-piece 140 will be described in detail.

An antenna 142 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 143 and is then filtered and synchronized by the filter section 141 having the plurality of piezoelectric vibrators 1.

In the present embodiment, the piezoelectric vibrators 1 include crystal vibrator sections 148 and 149 having resonance frequencies of 40 kHz and 60 kHz, respectively, which are the same frequencies as the carrier frequency.

In addition, the filtered signal with a predetermined frequency is detected and demodulated by a detection and rectification circuit 144.

Then, the time code is extracted by a waveform shaping circuit 145 and counted by the CPU 146. The CPU 146 reads the information including the current year, the total number of days, the day of the week, the time, and the like. The read information is reflected on an RTC 147, and the correct time information is displayed.

Because the carrier wave is 40 kHz or 60 kHz, a vibrator having the tuning fork structure described above is suitable for the crystal vibrator sections 148 and 149.

Moreover, although the above explanation has been given for the case of Japan, the frequency of a long standard wave is different in other countries. For example, a standard wave of 77.5 kHz is used in Germany. Therefore, when the radio-controlled timepiece 140 which is also operable in other countries is assembled in a portable device, the piezoelectric vibrator 1 corresponding to frequencies different from the frequencies used in Japan is necessary.

Since the radio-controlled timepiece 140 according to the present embodiment includes the piezoelectric vibrator 1 having excellent performance, it is possible to provide the radio-controlled timepiece 140 having excellent performance.

The present invention is not limited to the above-described embodiments.

In the first embodiment, the crystal substrate etching method has been described by way of an example of the case of manufacturing a crystal piezo-electric vibrating reed. However, the present invention can be applied to a case of manufacturing other crystal devices such as an acceleration sensor.

In the first embodiment, the method of manufacturing a package according to the present invention has been described by way of an example of a piezoelectric vibrator using a tuning-fork type piezoelectric vibrating reed. However, the method of manufacturing a package according to the present invention may be applied to a piezoelectric vibrator using an AT-cut type piezoelectric vibrating reed (a thickness-shear type vibrating reed).

In the first embodiment, the metal mask for dry-etching is formed by etching the metal film using the resist pattern as a mask. However, the metal mask may be formed by press working. However, the present embodiment is superior in that it is possible to form the metal mask with high accuracy and to form a fine piezoelectric vibrating reed with high accuracy.

In the first to third embodiment, anodic bonding, hydrogen bonding, and room-temperature bonding have been described as an example of a substrate bonding method. However, other substrate bonding methods other than anodic bonding, hydrogen bonding, and room-temperature bonding may be used.

What is claimed is:

1. A method of etching a crystal wafer comprising:
securing the crystal wafer onto an auxiliary substrate made of a material which has an etching rate nearly equal to an etching rate of the crystal wafer;
forming a metal mask on the crystal wafer;
dry-etching the crystal wafer through the metal mask at a depth deep enough to etch the auxiliary substrate.

2. The method according to claim 1, wherein the material mainly comprises a silicon oxide.

3. The method according to claim 1, wherein the material is crystal.

4. The method according to claim 1, wherein securing the crystal wafer onto an auxiliary substrate comprises anodically bonding the crystal wafer onto an auxiliary substrate.

5. The method according to claim 1, wherein securing the crystal wafer onto an auxiliary substrate comprises hydrogen-bonding the crystal wafer onto an auxiliary substrate.

6. The method according to claim 1, wherein securing the crystal wafer onto an auxiliary substrate comprises room-temperature bonding the crystal wafer onto an auxiliary substrate.

7. The method according to claim 1, wherein forming a metal mask on the crystal wafer comprises forming a metal film on the crystal wafer.

8. The method according to claim 7, wherein the metal film comprises a base film made of chromium and a protection film made of gold.

9. The method according to claim 7, wherein forming a metal mask on the crystal wafer comprises forming a photoresist film on the metal film.

10. The method according to claim 9, wherein forming a metal mask on the crystal wafer comprises exposing the photoresist film in a pattern to light.

11. The method according to claim 10, wherein forming a metal mask on the crystal wafer comprises developing the photoresist film to partially remove the photoresist film in the pattern.

12. The method according to claim 11, wherein forming a metal mask on the crystal wafer comprises etching the metal film through the partially removed photoresist film.
